(19) United States
(12) Patent Application Publication
(10) Pub. No.: US 2013/0163787 A1
(43) Pub. Date: Jun. 27, 2013

(54) Electronically Orbited Speaker System

(71) Applicant: Nancy Diane Moon, Del Mar, CA (US)

(72) Inventor: Nancy Diane Moon, Del Mar, CA (US)

(73) Assignee: Nancy Diane Moon, Del Mar, CA (US)

(21) Appl. No.: 13/336,970

(22) Filed: Dec. 23, 2011

(51) Int. Cl. H03F 99/00

(52) U.S. Cl. 381/120

(57) ABSTRACT

Exemplary embodiments are directed to a sound modification system and loud speaker system. The system may impose amplitude and frequency modulation on to a signal representing the output of an electrical musical instrument or other sound source while also imposing a sense of movement of the sound to the listener. Further, the system may simultaneously amplify sound signals without the amplitude, frequency and spatial sense of modulation or a different sense of modulation. The system combines a plurality of speaker transducers, a plurality of amplifiers and digital signal processors to provide a flexible, portable and practical sound modification and amplification system.

### BACKGROUND OF THE INVENTION

Musical organs have always suffered from lack of expression because the tones produced were simply keyed on and off, could be sustained indefinitely with no attack or decay and were rather pure, unchanging tones. In wind-driven pipe organs, a tremulant varied the wind pressure at a sub-audible rate imparting a vibrato, or pitch variation, to the tones of the pipes, thus adding excitement to the sound. Often multiple tremulants were used for separate ranks of pipes.

In electric organs, the vibrato effect is often imparted electronically; though, this is less than ideal as the sound is too precise and comes from a single speaker. In the case of the pipe organ, the pipes are physically spread; and the sounds comes from multiple directions. To achieve both the vibrato and spatial effect for electric organs, it became common to use an orbiting speaker where the sound sprays in different directions as the sound transducer spins about.

As the transducer orbits; the apparent source of sound, the mouth of the horn, moves toward and away from the listener. As the source moves toward the listener, the pitch would rise; and as the sound moved away, the pitch would fall. This pitch change is due to the Doppler Effect. The sound would reflect from various surfaces in the room, producing the spatial effect. More recently, electric guitar players have used orbiting speakers to add similar excitement to their playing.

While mechanically-orbited speakers have been used very successfully in the past, they suffer from several drawbacks. To produce the vibrato effect over the desired range of musical frequencies, the transducer must spin. The speaker cabinet must be rather large and heavy, making it difficult to move to live shows. The mechanical parts are delicate, requiring frequent maintenance. Attempts have been made to implement mechanically-orbited speakers with rotary joints to conduct sound signals to the orbiting transducers, but noise from the sliding contact and maintenance issues caused this approach to be abandoned.

Synchronizing multiple mechanically-orbited speakers is difficult, and a single physically rotating transducer has limited sound volume output. Venues have grown in size; and audiences have come to expect a full sound, so many performers resort to placing the orbiting speaker in a sound-isolated location, using a microphone and sound amplification system with multiple speakers.

Because the physical size of the orbiting speaker defines the acoustic performance, smaller and less expensive mechanically-orbited speakers do not achieve the desired musical effect, especially losing the desired frequency modulation by only rotating instead of orbiting.

Often mechanically-orbited speakers have only two speeds and no opportunity to vary the effect without physically modifying the speaker; thus, having a very limited expressiveness.

Keyboard players often have two or more instruments, or even one instrument, that can emulate more than one acoustic instrument, such as a synthesizer, that can produce tonewheel organ or piano sounds. Orbiting speakers have difficulty reproducing piano sounds without coloring and cannot reproduce uncolored piano and orbiting organ sound simultaneously.

There is a need in the art for a speaker system to amplify musical instruments that can produce the desired vibrato and spatial effect while being lighter and more rugged for transport, having no moving parts to avoid frequent maintenance, being able to achieve the desired vibrato and spatial effects in a low-cost configuration, or being able to be driven at high power levels and having multiple orbiting speakers ganged for higher sound levels, having the ability to vary the musical effect for increased expressiveness, and producing uncolored sound simultaneously with vibrato and spatial effects.

### BRIEF SUMMARY OF THE INVENTION

It is, therefore, the object of the present invention to enable a sound-system design for live performance of music with realistic tremulant and spatial effects in a physical configuration that lends itself to portability, low maintenance and low-cost manufacture. Instead of mechanically-orbited sound transducers, the present invention uses two or more transducers facing in different directions with the sound signal modulated separately for each speaker, as to impart the sense of orbiting as the sound reflects around the room.

The sense of direction of sound in the present invention is increased by using sound transducers or groups of transducers selected and arranged to produce the appropriate sound radiation pattern for the desired effect. The transducer array extends the tremulant effect to lower frequencies than that achieved by existing mechanically-orbited speakers.

Because the orbited effect is imposed electronically, the same set of amplifiers and sound transducers can be simultaneously used to amplify and project sound without the tremulant or other effects or with a different set of effects. This makes it practical for a musician to use a single sound system for organ sound reproduction with strong tremulant at the same time as electric piano having no tremulant, or with a light tremulant appropriate for the desired piano sound. This multiuse can be extended to any combination of instruments, voice or any other sound source.

Embodiments of the present invention lend themselves to addition of other sound effects particular to orbiting speakers, including simulation of horn-throat distortion, overdrive of the amplifier, amplifier- and speaker-cabinet emulation, and spatially diverse reverberation simulation. For various reasons described below, mechanically-orbited speakers have limitations on the amount of sound output a single unit can produce and ganging multiple units may result in the tremulant effect being degraded. The present invention achieves higher sound level from multiple transducers in a single unit and allows for multiple amplifier/transducer units to be ganged for even higher sound levels while maintaining the quality of the synchronized tremulant effect.

### BRIEF DESCRIPTION OF DRAWINGS

FIG. 1—shows the internal mechanism of a currently popular organ sound system.

FIG. 2—shows the outside view of the sound system of Figure.

FIG. 3—depicts a simplistic electronically orbited speaker.

FIG. 4—shows the effect of speaker transducer size on the radiation pattern at various frequencies.

FIG. 5—shows the sound radiation pattern of a horn-type transducer.

FIG. 6—shows a speaker enclosure where two transducers are used on each face forming a line array.

FIG. 7—shows a speaker enclosure where the cone-type transducers have a front-loaded horn.

FIG. 8—shows an electronically orbited speaker pole mounted on top of a subwoofer.

FIG. 9—shows a low-cost electronically orbited speaker with a horn upgrade.

FIG. 10—shows high power electronically-orbited speaker unit ganged for higher sound levels.

FIG. 11—shows the construction details of speaker.

FIG. 12—shows the signal connections of a simple electronically-orbited speaker.

FIG. 13—shows the signal connections of a self-contained, two-channel, electronically-orbited speaker.

FIG. 14—shows a low-cost, electronically-orbited speaker master unit.

FIG. 15—shows the tweeter upgrade unit that functions in conjunction with the master unit depicted in FIG. 14.

FIG. 16—shows a high-power master unit intended to be ganged with slave units.

FIG. 17—shows a high-power slave unit with outputs for daisy-chaining.

FIG. 18—shows the block diagram of a very high-power unit with separate rack mount preamplifier/DSP unit and power amplifiers.

FIG. 19—is a plot of the four amplitude envelopes of the four signals intended for the four sets of speakers, one signal for each face of the cabinet, in this case a gentle modulation.

FIG. 20—is a second plot of amplitude envelopes, in this case a medium modulation.

FIG. 21—is a third plot of amplitude envelopes, in this case an aggressive modulation.

FIG. 22—is a fourth plot of amplitude envelopes, in this case including the effect of the two sets of slots on each cabinet face.

FIG. 23—is a fifth plot of amplitude envelopes, in this case including the effect of the two sets of slots on each cabinet face and internal reflections.

FIG. 24—is a signal flow diagram of a basic DSP.

FIG. 25—is a signal flow diagram of a fully featured DSP.

FIG. 26—is a plot of horn-throat distortion over frequency.

### DETAILED DESCRIPTION OF THE INVENTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance or illustration” and should not necessarily be construed as preferred or advantageous over other exemplary embodiments.

This detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

In particular, the exemplary embodiment is described in terms of a unit with four faces with associated sound transducers; but this number could be any number from two to some larger number limited by cost and complexity concerns. The faces of the unit may be deployed horizontally, vertically or in any configuration where the sound of two or more transducers is directed in different directions.

In the exemplary embodiment, the signal processing function is described as, but not limited to, a digital signal processor. Some or all of the signal processing may be implemented by other means, such as, but not limited to, analog circuits, standard computing components, or any other electronic or electrical means.

The term “orbiting speaker” is used herein to mean any form of loudspeaker or sound-amplification device or sound-modification device intended to modulate or change the sound of a musical instrument or other sound source in a periodic way, especially to impart a periodic varying of pitch, amplitude or spatial perception. Orbiting speaker is intended to cover speakers that are commonly referred to as rotating or rotary speakers.

The terms “signal processor”, “digital signal processor” or “DSP” may be a purpose designed computing device, a general purpose computing device, a collection of analog or digital electronic circuits, or a combination of any of the above.

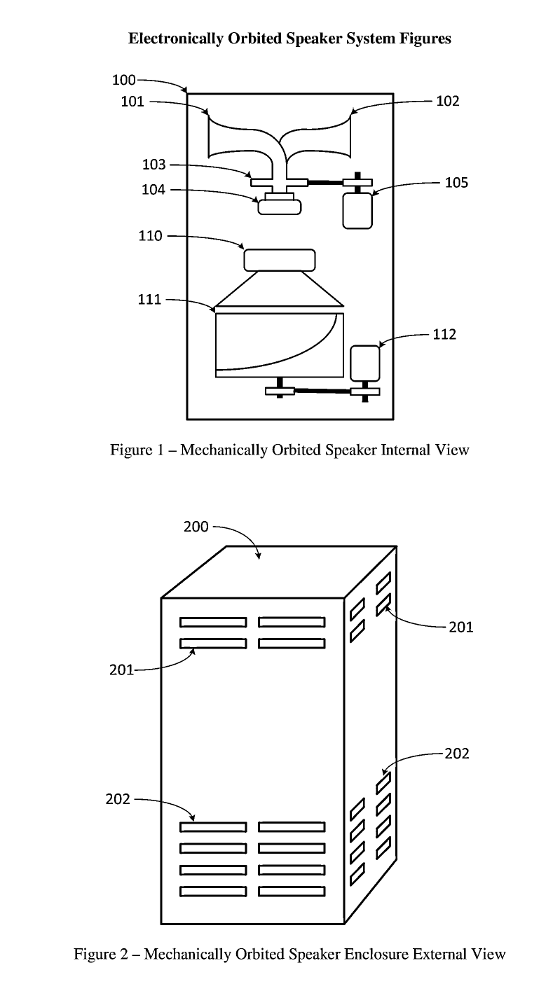

Existing orbiting speaker effect units are available in two forms: mechanical or electronic. The mechanism of the mechanical-type orbiting speaker is depicted in FIG. 1. The cabinet 100 is usually made of heavy wood to support the spinning machinery. The high frequencies are reproduced by a rotary horn 101 at the top of the cabinet and the low frequencies are reproduced by a cone-type speaker 110 at the bottom.

The rotary horn 101 is counter-balanced by a dummy horn 102. Sound is produced by a compression-driver unit 104 and is passed upward through a rotary joint and pulley 103. The horn assembly is rotated by an electric motor and belt 105. In most modern orbiting speakers, there is a second motor, not shown, to rotate the horn at a different speed, providing both a high- and a low-speed modulation effect.

The low-frequency, cone-type speaker 110 fires downward into a rotating drum 111 made of light-weight wood or other material. The drum has a scoop-shaped section that turns the sound toward the side of the cabinet 100 where there are slots to allow the sound to exit the cabinet. The drum 111 is rotated by the electric motor and pulley system 112 Like the horn in modern units, there are two motors, one for high speed and one for low speed. The second motor and clutching system is left out of the diagram for simplicity. The drum 111 is typically rotated in the opposite direction than that of the horn 101. Because of the limitations of the size of the low-frequency transducer and rotary drum, there is little frequency modulation effect; and the amplitude modulation is imparted largely by the mouth of the deflector drum passing by the slots in the cabinet.

As the playing style of many tonewheel organists includes switching often between the high speed and low speed or even stopping rotation of the speakers, the belts and clutching mechanism requires frequent maintenance.

FIG. 2 depicts the outside of the cabinet 200 of a typical mechanically-orbited speaker. The size of the cabinet affects the sound and only cabinets in a narrow range of size and particular configuration achieve the desired effect. In particular, there are slots on all four sides of the cabinet to allow sound to exit. One set of slots 201 at the top interact with the rotating horn and vary the amplitude and frequency response of the high-frequency sound as the horn spins. The other set of slots 202 interacts with the cone speaker and rotating drum to vary the amplitude and frequency response of the lower frequencies.

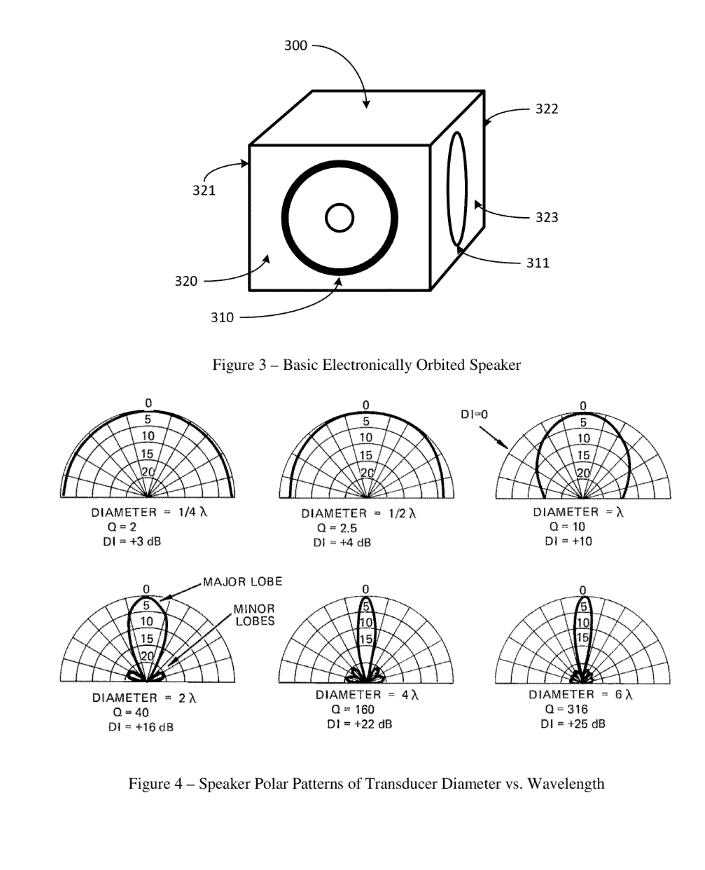

The solution to the needs enumerated above is the electronically-orbited speaker of the present invention described herein. As shown in FIG. 3, a simple exemplary embodiment would consist of four separate acoustic transducers mounted on the four vertical faces 320, 321, 322, 323 of a box 300. Each transducer would be driven by a separate electronic amplifier. The amplitude of drive to each transducer is modulated by any electronic means. Improvements in high-power, class D audio amplifiers and switch-mode power supplies make it very practical and cost effective to have several amplifiers in one product.

In this embodiment, the sound signal from the organ or other musical instrument is taken as input to a digital signal processor, known as a DSP. The DSP would divide the signal into four signal streams. Each stream is modulated to impart an amplitude envelope that corresponds to the sound level that would be experienced by an orbiting sound source as it passed across a face. If the virtual orbiting sound source were pointed toward the listener, the DSP sends the maximum signal to the amplifier driving the transducer 310 on the front face 320 of the box 300. As the virtual sound source orbits to the right, the transducer 311 on the right side 323 of the box 300 is driven at higher levels; and the drive to the front transducer 310 is reduced.

When the virtual orbiting sound source is pointing at the corner of the box, the drive level to both the front and right side transducers 310, 311 is equal and at some typically lower power level, thus sounding like a single transducer pointed toward the corner of the box. This process continues, handing off the audio power from one transducer to the next as the virtual sound source orbits in a complete circle. This is a very simple description of the action of the electronically orbited speaker; and there are many factors that improve the musical effect, which will be described.

Fundamental to the success of the orbiting speaker effect is the radiation patterns of the acoustic transducers. The patterns must be narrow enough to provide the desired effect of the sound spraying out in different directions as the virtual sound source orbits. If the transducers have a very wide radiation pattern, there is little change in the sound no matter which way the speaker is pointed. The ideal transducer pattern for an electronically-orbited speaker with four sides would be a single beam approximately 90° wide. However, as shown in FIG. 4, real transducers do not have a single radiation pattern for all frequencies. Higher frequencies tend to have a very narrow pattern; while at lower frequencies, the pattern broadens until it becomes almost omnidirectional. This effect is dominated by the size of the transducer. A transducer with an effective diameter of approximately one wavelength produces the ideal 90° pattern.

Sound wavelength formula

wavelength=344/f

f in Hertz

wavelength in meters

FIG. 5 shows the radiation pattern of a horn-type transducer of approximately the same size as the horn used in the classic mechanically-orbited speaker. The mouth of the horn is 0.12 meters in diameter. Using the formula of paragraph [0055], the mouth is one wavelength at 2866 Hertz. The radiation pattern at 500 Hertz is almost omnidirectional, such that rotation of the horn would not produce the orbiting sound-source effect. At 1 KiloHertz, the radiation pattern has only minor deviation from omnidirectional; so the effect of rotation would be subtle. Only at 2 KiloHertz and above does the directionality of the horn significantly alter the sound when rotated and achieve the desired result.

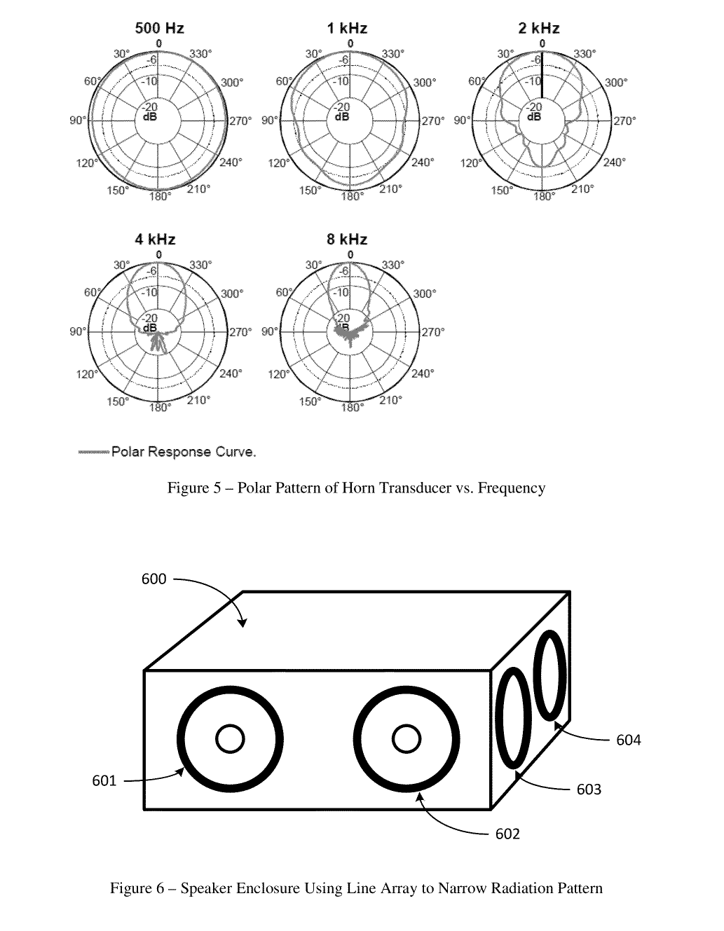

In FIG. 6 an exemplary embodiment 600 is shown that improves the sound radiation pattern of the mid-range frequencies, extending the orbiting sound-source effect to lower frequencies in a simple but effective manner. Considering a single cone-type transducer 601 of a typical 150 millimeter diameter, and using the formula of paragraph [0055], the transducer loses directionality below 2293 Hertz. This is not much different than the horn transducer analyzed above. By adding a second identical transducer 602 spaced 0.75 meter center-to-center, a line array is established. The effective diameter for the horizontal radiation pattern calculation becomes 0.75 meter, considerably narrowing the pattern at lower frequencies. The proper directional radiation pattern would be maintained down to 458 Hertz, thus extending the orbiting sound-source effect into the middle of the musical spectrum in a simple and cost-effective manner. The scheme is extended to each face with the transducers 603 and 604 making up the line array of the right face.

Classical mechanically-orbited speakers often have a deflector plate attached to the mouth of the horn in an attempt to spread the sound radiation pattern at higher frequencies. In the electronically-orbited speaker system, the DSP may divide a frequency band dedicated for a specific transducer into sub-bands and modulate the signal with different amplitude envelopes for each sub-band to equalize the sound radiation pattern between sub-bands. Alternatively, the amplitude envelopes may be selected to emphasize the difference of radiation pattern between sub-bands. By doing so under player control, the electronically-orbited speaker system can emulate the sound of different models and configurations or modifications of classical orbiting speakers.

Some players prefer to use two classical mechanically-orbited speakers. Each rotor in each speaker rotates at a slightly different rate, making for a very complex variation in the tremulant effect. The DSP of the electronically-orbited speaker system may use a plurality of amplitude envelopes running at different speeds to provide this complex tremulant effect. The delays to impose a reverberation effect may be different for each amplitude envelope to provide the illusion that the virtual rotors are in different physical locations.

Mechanically-orbited speakers often have a feature where the rotor is stopped by a brake with the transducer facing front to provide maximum sound level in the non-orbiting configuration. The DSP of the electronically-orbited, upon receiving a command to stop the virtual orbiting, may continue the current orbit until the virtual transducer reaches front center where it may stop and ramp the amplitude to maximum regardless of the amplitude envelope at that point.

As the virtual orbiting transducer accelerates or decelerates, the amplitude envelope may be changed to emphasize the tremulant effect.

The size of a transducer also affects the efficiency in converting the electrical signal to sound. A smaller transducer works better at higher frequencies while a larger transducer is needed to reproduce lower frequencies. The electrical signals may be divided into bands appropriate for each transducer by a crossover network and each transducer driven with only the signals it can reproduce well. Dividing the musical spectrum up to be reproduced by separate transducers also helps the variation in radiation pattern with frequency. A smaller transducer maintains a narrow radiation pattern only in the upper frequencies. A larger transducer provides a narrow radiation pattern at lower frequencies, though even a very large transducer becomes omnidirectional at the lowest musical frequencies.

This problem of needing to use different sizes of transducers is not unique to electronically-orbited speakers. The best mechanical-orbited speakers use a rotating high frequency transducer and a separate rotating low frequency transducer. To deepen the musical effect, the two transducers are rotated in opposite directions.

The electronically-orbited speaker in another exemplary embodiment uses a high frequency transducer and one or more low frequency transducers on each of the four faces of the box. Each transducer or transducer array has an associated amplifier. The DSP divides the input signal into two frequency bands performing the crossover function, one band for the high frequency transducers and one band for the low frequency transducers. The DSP then divides the signal for each band into four signal streams for each of the transducers on each face of the box. Each of the two sets of four streams is coupled to the associated amplifier. The orbiting is imparted by the same amplitude envelope method as described above. In this case, the high frequency set is orbited in one direction and the low frequency set is optionally orbited in the opposite direction.

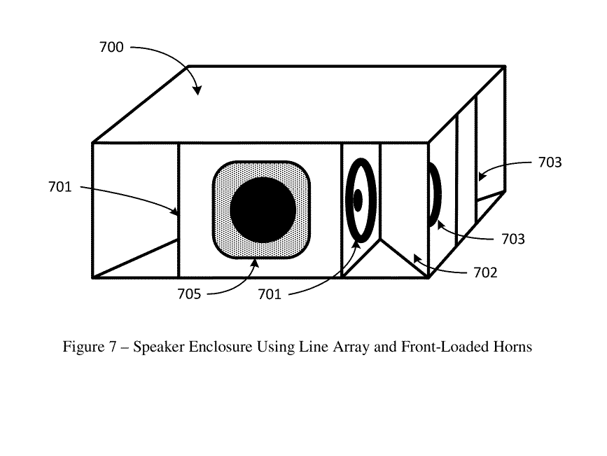

FIG. 7 shows an electronically-orbited speaker 700 comprised of a horn-type transducer 705 mounted in the center of each face and a pair of cone-type transducers 701 with front-loaded horns 702, 703 at the extremes of each face. The details of construction are shown in FIG. 11. The horn-type transducer 705 produces the desired narrow sound radiation pattern for the highest frequency band. The pair of cone-type transducers 701, by being driven with the same signal, operates as a line array giving the effect of a single larger transducer. This produces a sound radiation pattern appropriate for the mid-range frequency.

In FIG. 6 the transducers 601, 602 are spaced away from the corner of the cabinet because the large magnet structure of the high-power transducers restrict the placement, making the cabinet size larger for a given transducer-to-transducer separation distance. In FIG. 7 the magnet structures of the transducers 701, 703 do not mechanically interfere because they are behind a front-loaded horn 702 made up of the transducer baffle, the walls of the cabinet and the septum. This arrangement allows the center of sound radiation of each transducer to be as close to the edge of the cabinet as possible and provides some improvement in efficiency of the transducer.

The following describes three physical configurations of electronically-orbited speakers introduced so that the advantages of the present invention may be appreciated in the subsequent description. The size of the units may vary, with the low-cost units tending to be smaller and the high-power units tending to be larger and heavier.

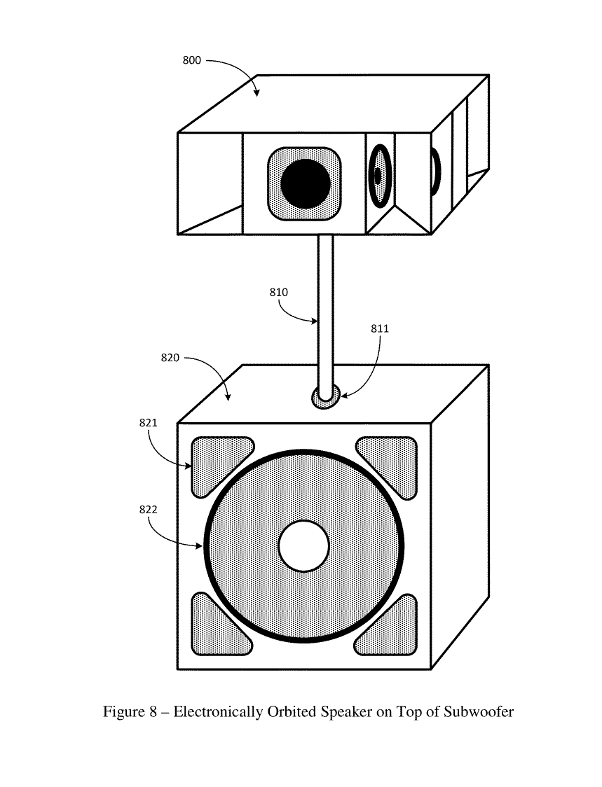

FIG. 8 depicts an electronically-orbited speaker 800 mounted on top of a subwoofer 820. The subwoofer 820 augments the frequency response of the system, producing most of the acoustic energy below approximately 300 Hz. A large cone-type transducer 822 is necessary to produce bass tones with reasonable efficiency. To extend the low-frequency response and further improve efficiency, a base-reflex design is used with ducted ports 821 in each corner. Other port configurations may be used, such as a single port or ports made from tubing, but the corner ports allow a small frontal area and the shape of the subwoofer cabinet to be close to a perfect cube, which minimizes the material and the overall weight of the cabinet. Also, the corner ports provide additional bracing to the speaker baffle, further reducing the weight of material needed for an acoustically rigid enclosure.

The electronically-orbited speaker 800 is mounted on a commercially available pole 810 inserted into a socket 811 in the top of the subwoofer 820 and into another socket, not shown, in the bottom of the electronically-orbited speaker cabinet. Mounting the speaker high allows the sound to sweep around the room, unimpeded, for a more vibrant effect. The electronically-orbited speaker 800 may be used without the subwoofer 820 by mounting the electronically-orbited speaker 800 on a commercially available speaker stand (not shown), typically, but not limited to, a tripod type.

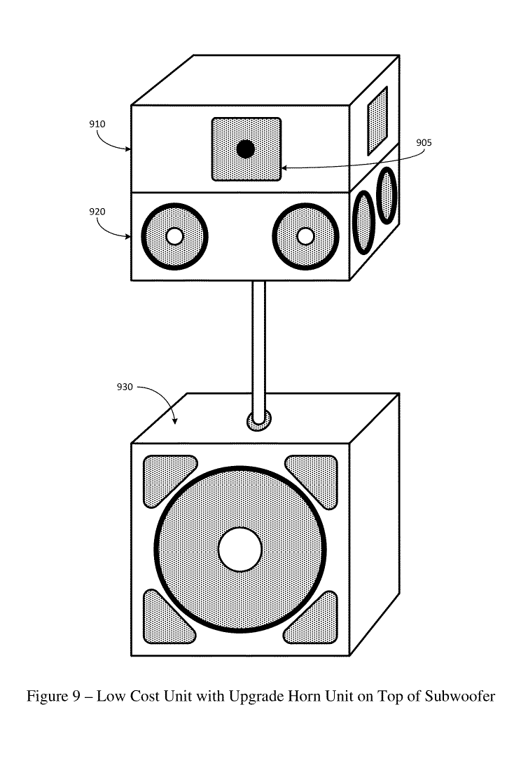

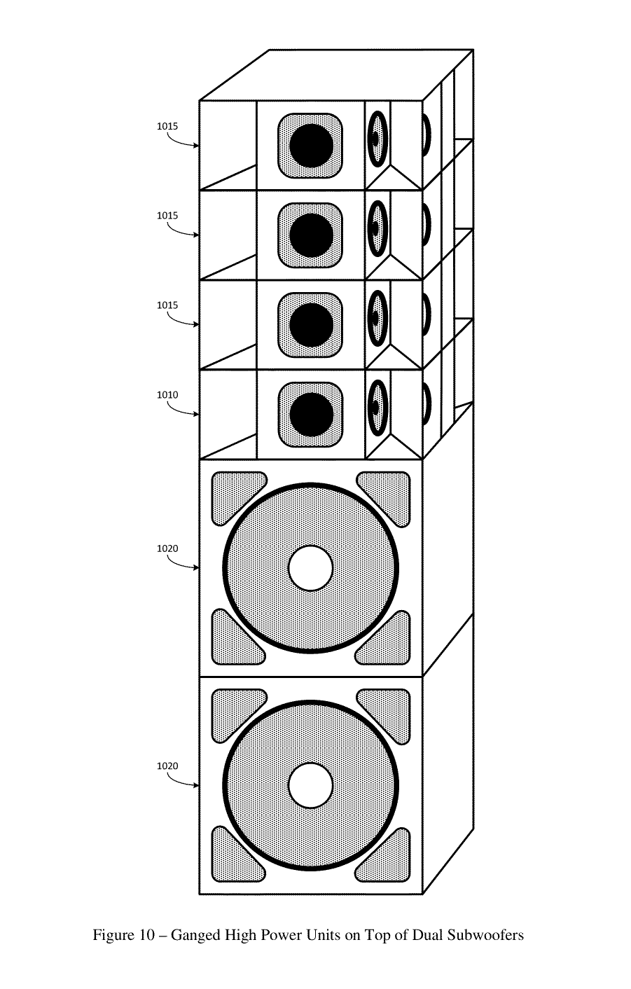

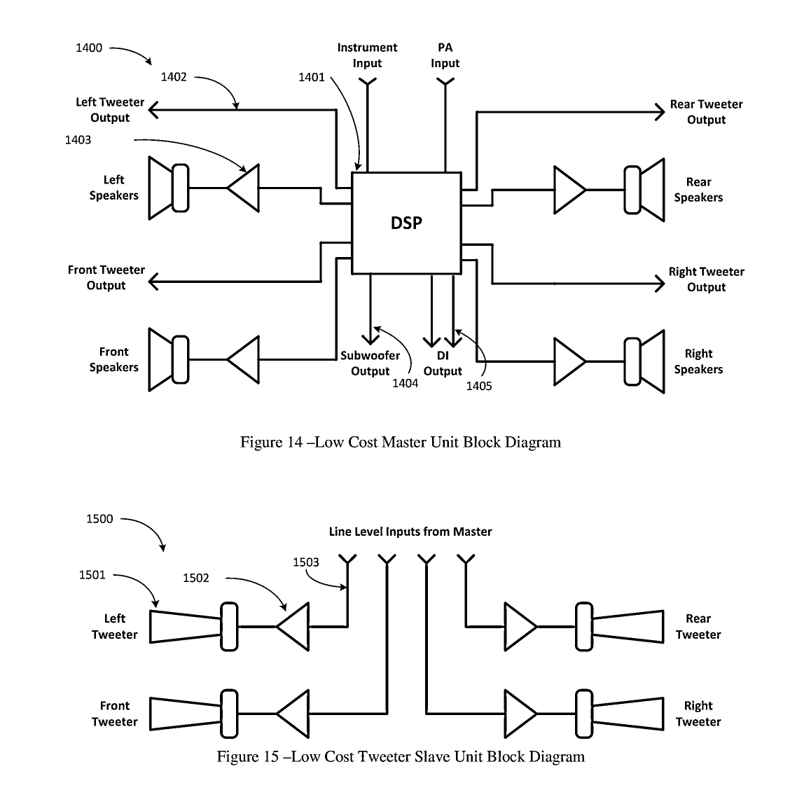

FIG. 9 shows a configuration that includes a low-cost, electronically-orbited speaker 920 employing only cone-type transducers pole mounted on a subwoofer 930 with a horn-tweeter upgrade unit 910 installed on top. The basic low-cost unit may be mounted on any type of speaker stand and operated at low- to medium-volume levels while producing the orbiting speaker effect. The subwoofer 930 may be added to increase bass response and provide a convenient speaker stand. The tweeter upgrade unit 910 with four horn-type tweeters 905 and four amplifiers may be added, with or without the subwoofer, to increase the volume and improve the rotating speaker effect by splitting the mid and high frequencies to separate transducers. The signal flow of low-cost master and tweeter units are described in FIGS. 14 and 15.

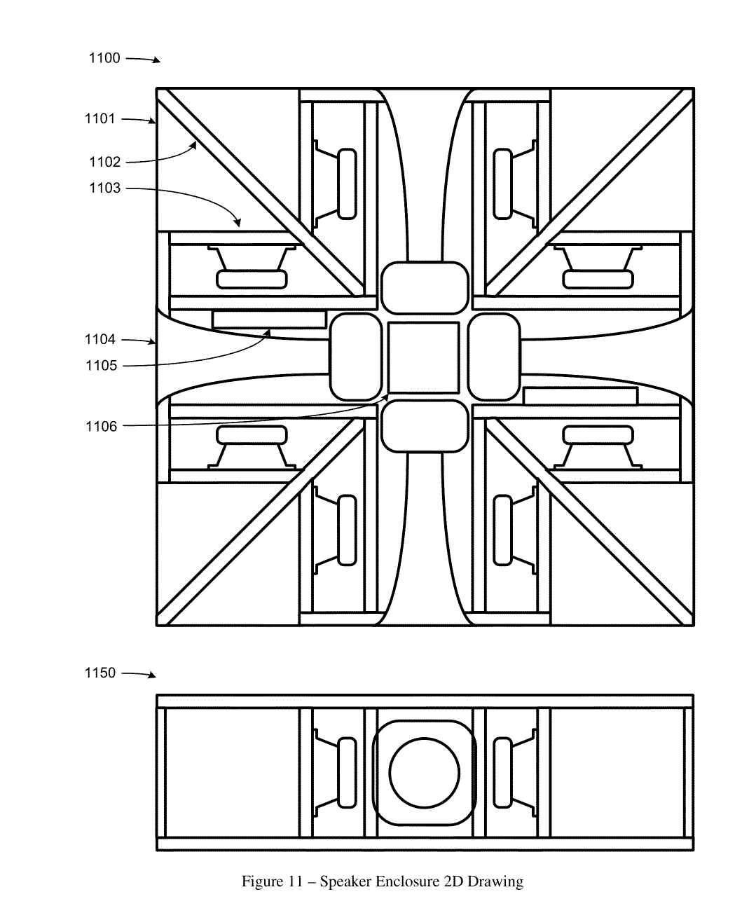

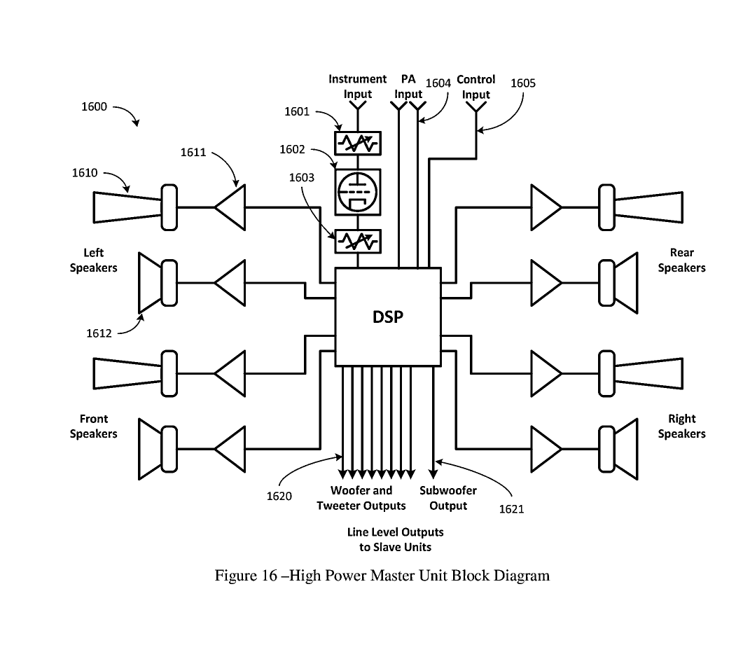

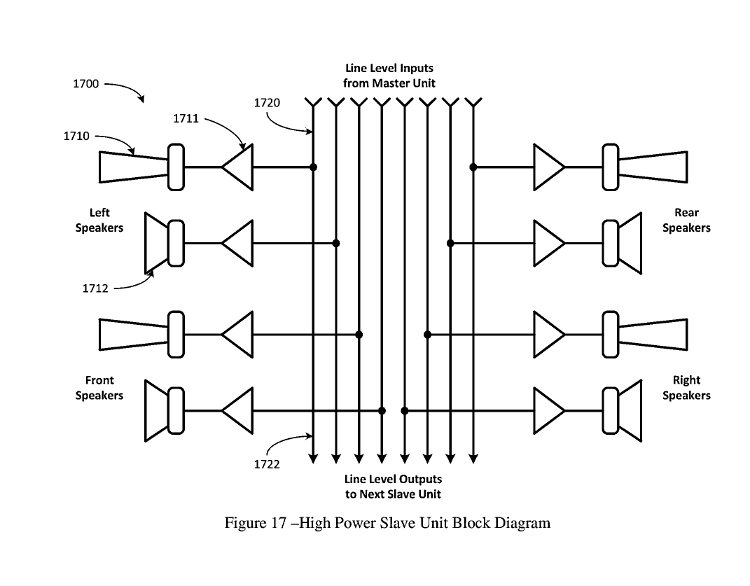

FIG. 10 shows a ganged stack of units for very high sound levels for large performance venues. The electronically-orbited speaker units 1010 and 1015 may be self-contained with internal electronics, or may house only the transducers with external rack-mounted electronics. If the units are self-contained with internal electronics, one unit would be the master 1010 with a DSP and complement of power amplifiers. The slave units 1015 would not have a DSP but would have the power amplifiers. The configurations of electronics for high-power units are described in FIGS. 16 and 17. This configuration may also be achieved by integrating multiple sets of transducers in a single cabinet. For example, the tweeters and midrange transducers may be integrated into the same cabinet as the subwoofer. Alternatively, multiple sets of tweeters and midrange transducers may be integrated into a single cabinet.

In either configuration, a single DSP would drive all units so that they would all virtually rotate in synchrony; and the sound would seem to emanate from a single point in the room. Similarly, the subwoofers 1020 would be stacked together to avoid bass cancellation caused by separation of bass transducers. For self-contained high-powered units, care must be taken to vent heat from the electronics out the sides of the units to allow vertical stacking.

A variation of the above configuration would consist of the DSP having eight channels for eight faces. The channels for the odd-number faces would drive the transducers in the master unit 1010. The even-number channels would drive the transducers in the slave unit 1015 immediately above the master unit 1010. The slave unit would be physically turned 45° to produce, in effect, an eight-face speaker. The remainder of the slave units would be driven alternately by odd and even channels and each turned 45° from the one immediately below. Although this adds complexity to the DSP unit, it provides a smoother transition as the virtual-sound source moves from one face to the next.

FIG. 11 shows 2D views of the construction of a high-power, electronically-orbited speaker unit. In the top view 1100, the top is removed to show the internal construction. The four faces are divided by walls on the diagonal 1102 that form one wall of the front-loaded horn space 1101. Each cone-type transducer 1103 is mounted in a baffle that forms the opposite wall of the front-loaded horn 1101. The horn-type transducers 1104 are mounted in the center of each face. Internal spaces around the horns are used for electronics modules 1105, 1106. The front view 1150 has the front panel removed to show the internal construction.

Class D power amplifiers can achieve high power with efficiency exceeding 90 percent, which reduces heatsink size and ventilation air requirements. Class D amplifiers of medium-power are available quite economically in a single integrated circuit package, while high-power amplifiers may be constructed with minimal component size and number. A switch-mode power supply eliminates the large and heavy 50/60 Hz power transformer and also operates at high efficiency. This makes it practical to have multiple amplifiers, one for each horn-type transducer and one for each pair of cone-type transducers. For extremely high-power applications, the electronics may be mounted external to the transducer cabinets, driven by cooling considerations.

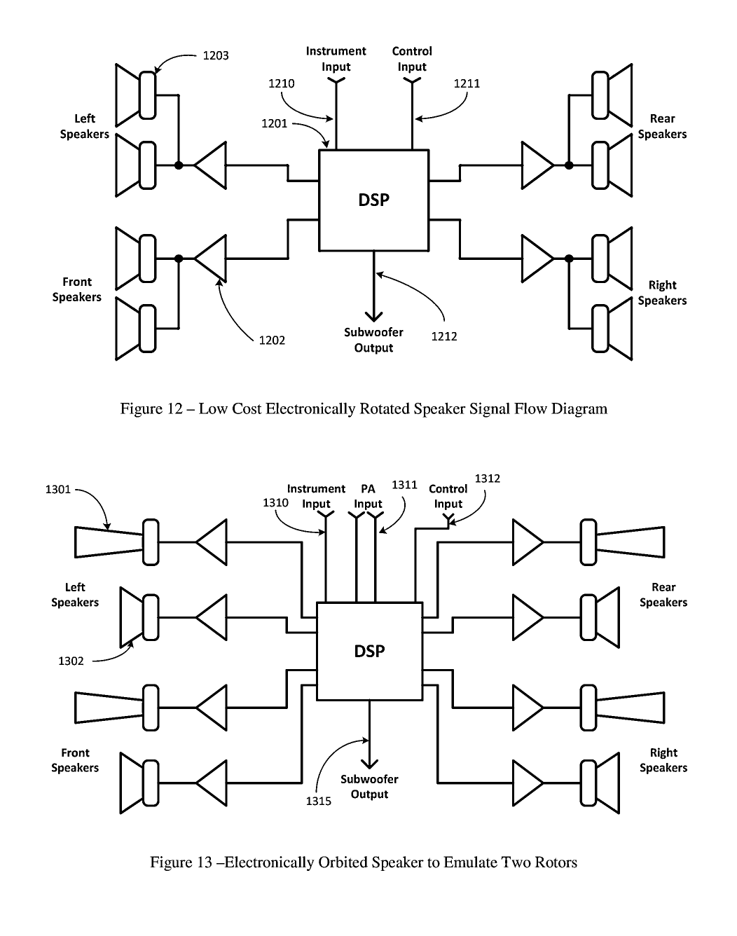

FIG. 12 shows the signal flow of a low-cost electronically-orbited speaker. A line-level audio signal is provided to the Instrument Input 1210 by the sound source, typically a musical instrument. The signal is processed by the DSP 1201 by being split into four signals used to drive each face of the unit. Each face has a dedicated power amplifier 1202 to drive the pair of cone-type transducers 1203. A line-level subwoofer output 1212 is filtered by the DSP to only allow the bass frequency signal to pass to the subwoofer for amplification and the larger transducer.

The control input 1211 may be of one or more types and multiple types may be incorporated into any particular embodiment. One interface may emulate the existing popular mechanically-orbited speaker with discrete signals for fast and slow speeds and a brake to stop rotation. Other control inputs may use the Musical Instrument Digital Interface (MIDI) protocol to control various parameters of operation including, but not limited to, fast and slow speed, stop, variations in speed for each of the high- and mid-frequency channels, acceleration and deceleration of the virtual rotors, crossover frequencies, envelope profile selection (described later), distortion effects thresholds and many other parameters. The MIDI interface may use the MIDI signaling definition or be implemented via Universal Serial Bus (USB) as are many musical instruments. The control interface is assumed to be present in all subsequent drawings and descriptions but not shown for simplicity and clearer understanding of the figures.

FIG. 13 shows the signal flow of an electronically-orbited speaker with cone-type transducers 1302 for the mid frequencies, and horn-type transducers 1301 for the high frequencies, and line-level output 1315 for the low frequencies to be routed to an external subwoofer. This specialization of type of transducers for each frequency band improves the matching of sound-radiation pattern for the desired effect. The cone-type transducer 1302 is shown as a single transducer for clarity. Typically, two or more transducers would be employed in a line array to produce the tight sound-radiation pattern required to produce the spatial effect.

The Instrument Input 1310 is divided into nine separate signals. Four signals are bandpass filtered by the DSP for the mid frequencies and four signals highpass filtered for the high frequencies. Pairs of signals, one mid and one high, drive each face. The ninth signal is routed to the subwoofer 1315. The PA Input 1311 is a stereo pair. It is similarly, but separately, split and processed by the DSP and summed at each of the nine outputs to the amplifiers. The right and left channels of the stereo pair are summed into the faces of the speaker with different gains to produce the desired stereo effect.

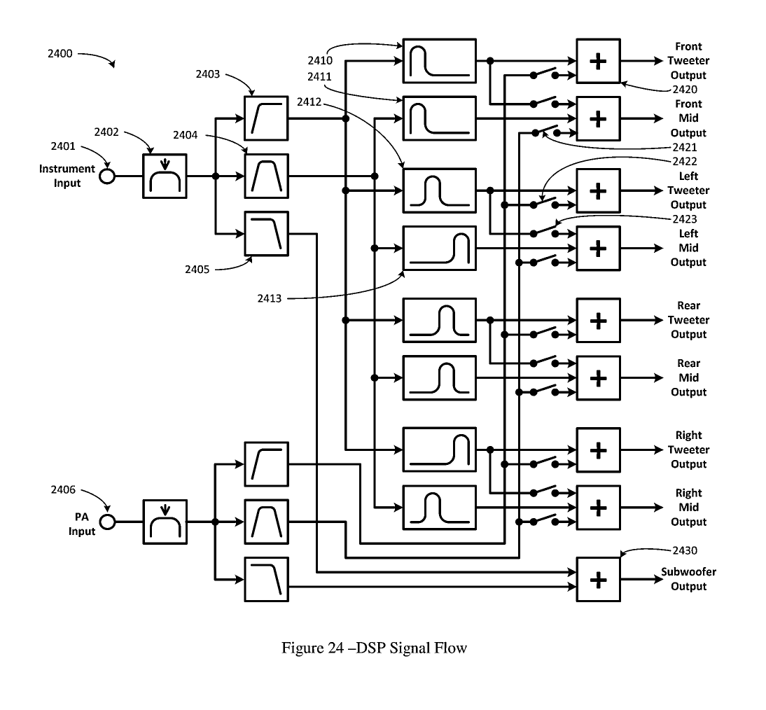

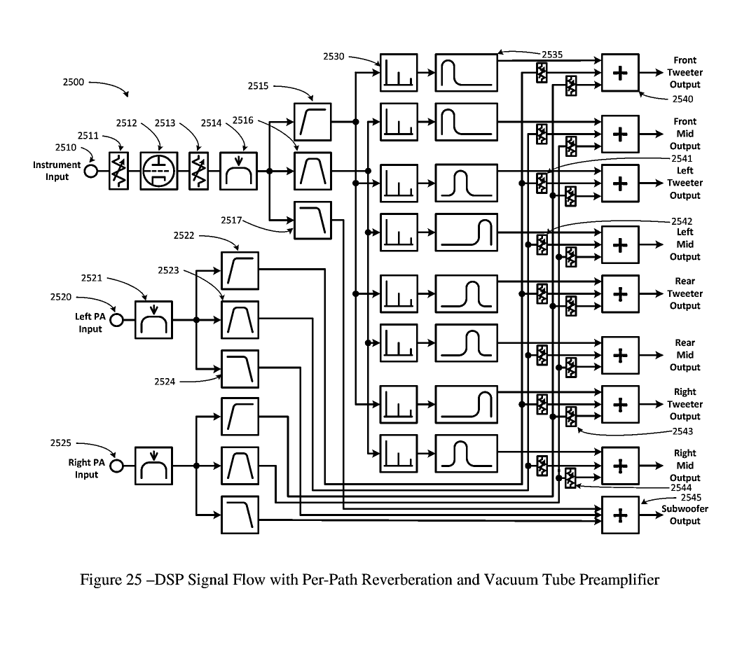

The Control Input 1312 provides the user the interface to change various parameters and to turn effects on and off. Details of the DSP signal flow are described in support of FIGS. 24 and 25.

FIGS. 14 and 15 show the signal flow for a low-cost configuration comprised of a master unit 1400 that may be used stand-alone or upgraded with the addition of the tweeter slave unit 1500. The signal flow of the master unit 1400 corresponds to the physical configuration 930 in FIG. 9. Similarly, the slave unit 1500 corresponds to the physical configuration 910 in FIG. 9.

The master unit 1400 is comprised of the DSP 1401, four amplifiers 1403 and the associated cone-type transducers for each of the four faces. This comprises the minimum set of components for the sound system to operate and would provide adequate sound reproduction in settings where high sound levels are not necessary. Also included are line-level outputs for four tweeter channels 1402 and a line-level output for an external subwoofer 1404. The number of faces and the number of amplifiers and sets of transducers could be two or more. Four faces are used here as an exemplary embodiment for illustration.

To upgrade the basic system comprised of the master unit 1400, the tweeter slave unit 1500 is added, comprised of line-level inputs 1503 routed from the master unit 1400, four amplifiers 1502 and tweeters 1501. The tweeters may be of the horn type for tight directional control of the high frequency output.

An alternative to the above upgrade configuration may be to include all eight amplifiers in the master unit 1400. When the tweeter slave unit 1500 is not plugged in, each transducer in the master unit 1400 would be driven by an individual amplifier 1403. The mid-range signals would be routed to both transducers on a face to produce the line array configuration. At higher frequencies, this line array would produce a very narrow sound-radiation pattern, which is not desirable. The high frequency signals may be routed to only one of the amplifiers and one transducer for each face, which would produce a radiation pattern appropriate for this frequency range. An eight pole, double-throw mechanical relay may do the switching. With the coil of the relay not energized, the transducers in the master unit 1400 are driven by separate amplifiers. A jumper in the plug for the slave unit 1500 energizes the relay coil and switches one amplifier per face to drive the tweeters in the slave unit 1500.

Another feature illustrated in FIG. 14 is the Direct Insert (DI) line-level output 1405. When using the existing rotatory speaker solution in either a live performance setting or a studio, the practice is to put the rotary speaker in a sound isolated location and place a stereo pair of microphones at strategic locations near the speaker. The signal from the microphones is routed to the mixing board and then on to the house sound system or is recorded. The DI output 1405 provides the function of the use of the sound isolation and microphones without the drawbacks. The sound from each of the multitude of signal paths in the DSP are combined into a stereo pair and sent through a pair of line-level outputs directly to the mixing board. This feature may be incorporated into any of the configurations shown. The signals may have additional modulation to emulate the directional characteristics of the speaker system that are lost by the direct connection. In particular, the signals would be filtered such that the high frequency content would be reduced when the virtual transducer is pointed away from the listener.

FIGS. 16 and 17 show features of a self-contained master unit and slave unit intended for live performance applications and may be ganged for very high sound levels. The signal flow diagram of the master unit 1600 in FIG. 16 corresponds to the physical configuration of the high power master unit 1010 in FIG. 10. The signal flow diagram of the slave unit 1700 in FIG. 17 corresponds to the slave unit 1015 in FIG. 10.

The master unit 1600 may include a vacuum tube preamplifier 1602 at the instrument input to provide warmth and soft compression favored by musicians. The vacuum tube amplifier stage may include a variable gain component 1601 before and/or a variable gain component 1603 after the amplifier to adjust the effect of the vacuum tube amplification on the signal. This effect may be simulated by the DSP instead of, or in addition to, the vacuum tube preamplifier.

In the master unit 1600, the power amplifiers 1611 contained in the unit drive the transducers 1610 and 1612. There are four high frequency outputs to drive the four tweeters 1610 and four mid frequency outputs to drive the cone-type transducers 1612. The same signals that drive the internal amplifiers are duplicated and used to drive the slave unit 1700 via the line level outputs 1620, with four signals dedicated for tweeters and four signals for mid-range transducers. The control input 1605 provides external user interface. The external control device may be as simple as the “half-moon switch” commonly mounted on a tonewheel organ, dedicated controls on an musical instrument panel or as complex as a computer with a full complement of parameter controls.

In the slave unit 1700, the line-level inputs 1720 are routed to the appropriate power amplifier 1711, which in turn drives a tweeter 1710 or mid-range transducer 1712. The line-level signals are also routed to an output connector or connectors 1722, which makes the signals available for an additional slave unit 1700 to be driven by a single master unit 1600. In this manner, the line-level signals may be daisy-chained from master to slave to slave and so on. The line-level inputs and outputs may be implemented as analog but are not limited by this exemplary embodiment. The inputs and outputs may be digital in any of a number of configurations, such as but not limited to, Ethernet, SPDIF, optical or coaxial.

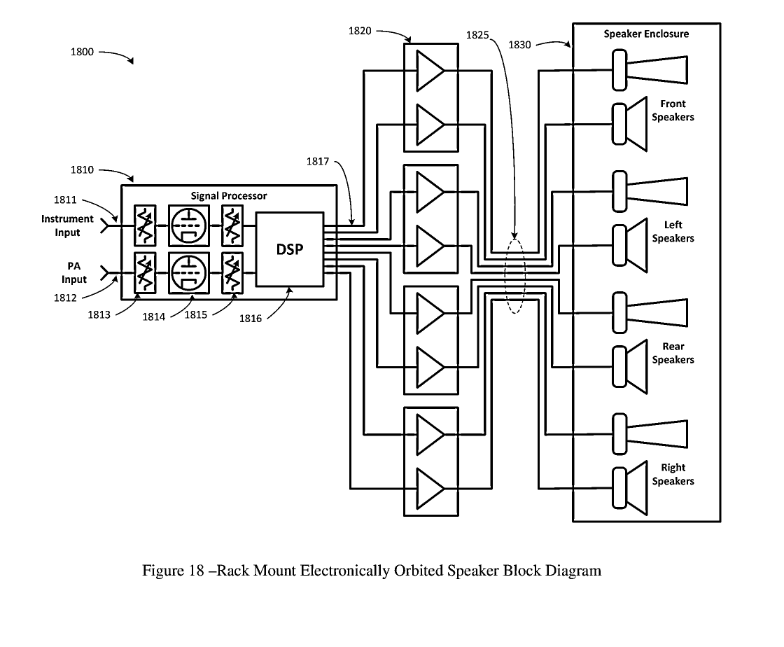

FIG. 18 shows an embodiment comprised of rack mounted electronics and a separate speaker cabinet or cabinets 1800. This configuration is especially suitable for very high power applications where the cooling of the power amplifiers embedded in the speaker cabinet is problematic and stacking the cabinets in the ganged configuration reduces the surfaces available for cooling vents. The rack mount signal processor 1810 receives the input signals from the primary musical instrument 1811 and a secondary input channel 1812. As an exemplary configuration, this signal processor is comprised of a vacuum tube preamplifier 1814 on each signal input and a digital signal processor 1816. The number of signal inputs 1811, 1812 is not limited to two and may be any number from one to as many desired. The gain of each input channel is separately controlled, providing the function of an audio mixer. Thus, the electronically-orbited speaker can serve as a complete sound system for live performance of multiple instruments and vocals.

The vacuum tube preamplifier 1814 is an optional feature to add warmth and soft compression to the sound. This feature may be implemented in the DSP or with analog circuits other than a vacuum tube. To control the contribution of the tube sound, a pre-gain control 1813 and post gain control 1815 are optionally included.

The rack mount power amplifiers 1820 are standard commercial products typically provided with a stereo pair of channels in one unit. The signal processor 1810 and the power amplifiers 1820 may be mounted in the same rack case for ease of transport. For an exemplary configuration with tweeters and midrange transducers deployed on the four faces of the speaker enclosure 1830, four stereo power amplifiers are required. Typically, short individual cables connect the signal processor 1810 to the inputs of the power amplifiers 1820. A heavier cable or cables 1825 may connect the power amplifier 1820 outputs to the speaker enclosure 1830. The speaker enclosure 1830 may be in the physical configuration shown in FIG. 7 and may be ganged with multiple speaker enclosures and/or subwoofers as shown in FIG. 10.

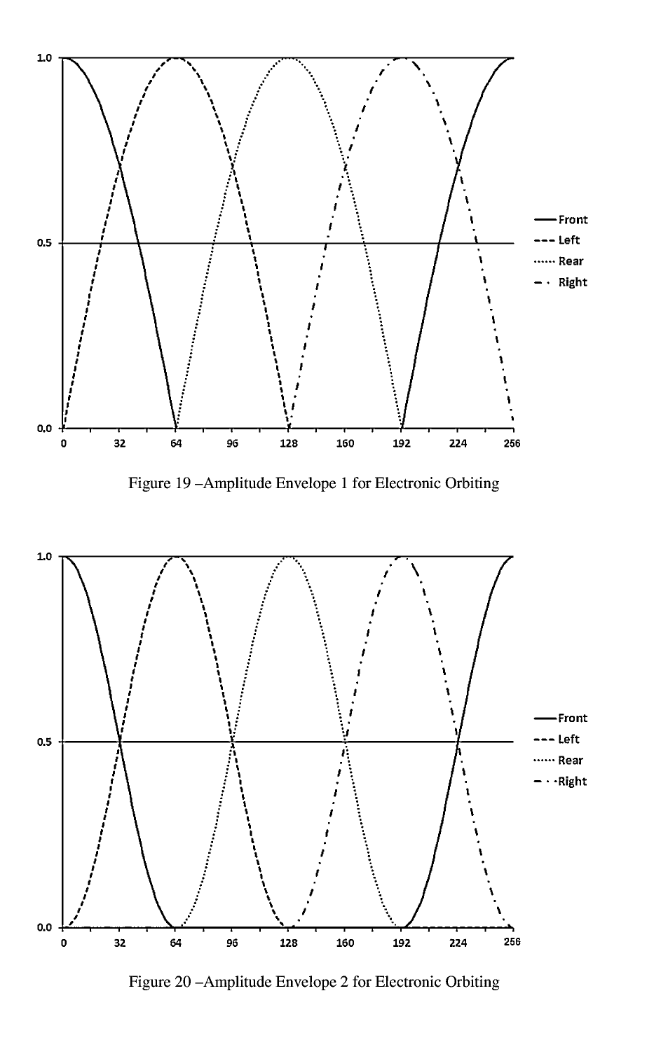

The fundamental orbiting speaker effect is produced by splitting the input signal into one path for each face of the speaker enclosure and amplitude modulating the paths separately to sweep the sound in a complete circle. The sound is physically moved by imposing the appropriate amplitude envelope on the signal paths. The process of physically moving the apparent sound source and direction in a circle imposes both amplitude and frequency modulation on the sound. The amplitude modulation can be depicted as amplitude envelopes as shown in FIGS. 19, 20, 21 and 22.

FIG. 19 is a plot of a simple set of amplitude envelopes for a four face speaker enclosure. The vertical axis indicates the amplitude attenuation imposed on the signal. The horizontal axis indicates the rotational step. In this exemplary embodiment, the circle is divided into 256 steps. The DSP counts the steps and wraps around at the end. At count 0 the signal for the transducers on the front face are at full volume while all other signals are fully attenuated. As the steps increase, the front face signal is attenuated and the left face signal is increased. At step 64, the front face signal is fully attenuated and the left face signal is at full volume. This process continues until the count reaches 256, which is the same condition as count 0.

This process is repeated for each orbit of the sound. The slow-speed effect is called “Chorale” and typically orbits at 45 RPM. The fast-speed effect is called “Tremolo” and orbits at approximately 400 RPM. Some models of mechanically-orbited speakers have multiple pulleys to change the orbiting speed but require disassembly of the cabinet to make the change. In the electronically-orbited speaker several orbital speeds are available, changed via the external control input. Similarly, the external control input provides selection of multiple amplitude envelopes for different orbiting effects.

To orbit in the opposite direction, the count is stepped down instead of up. To produce these amplitude envelopes, a look-up table may be used or the values of the envelope calculated in real time. In the case of the look-up table, the full rotation may be represented by the segment of one of the envelopes from step 0 to 64. The remainder of the circle may be simply produced by modulo arithmetic and incrementing the look-up table pointer up or down for the positive or negative slope of the curve.

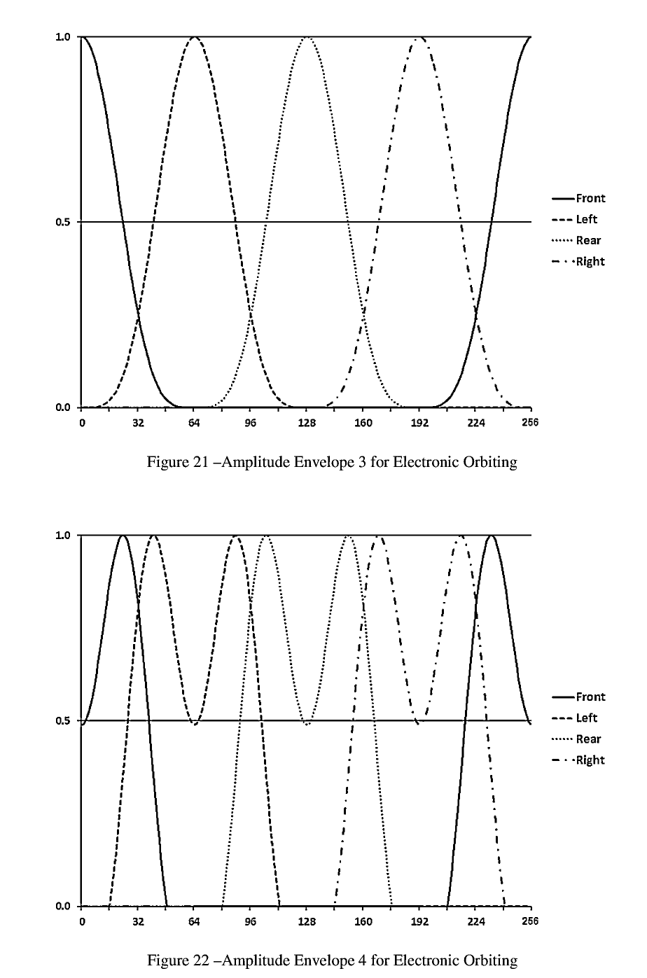

The amplitude envelopes of FIG. 19 would produce a gentle tremulant effect with large overlap of the signals between faces. FIG. 20 is a moderate tremulant with less overlap and sharper amplitude peaks. FIG. 21 is more aggressive with even less overlap and tight amplitude peaks. These simple amplitude envelopes emulate a transducer orbiting without the effect of the cabinet, such as when players remove the back or even the whole top of the speaker cabinet for more volume.

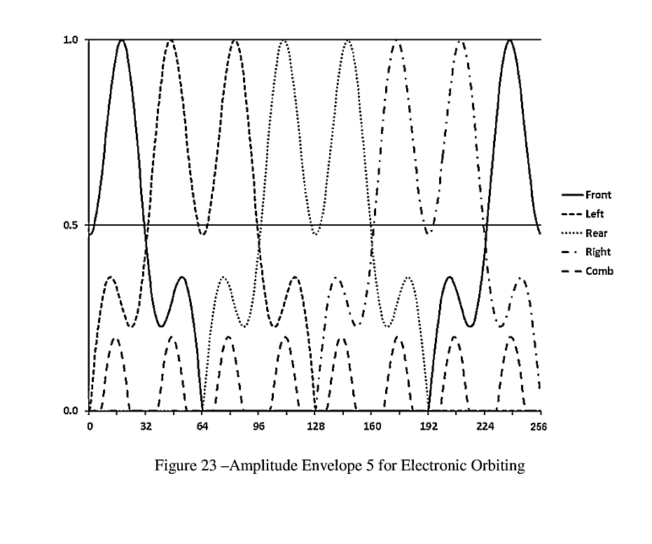

The Amplitude envelopes of FIG. 22 introduce double peaks which emulate the orbiting transducer passing and interacting with the slots on the side of the cabinet. This makes for sharp transitions from one face to the next with the dip in amplitude when directly aligned with the face and blocked by the cabinet side between the slots. FIG. 23 is the most complex exemplary set of amplitude envelopes. The envelope for each face has a double peak to emulate the cabinet slot interaction. In addition, there is a smaller peak coupled with a peak of a comb filter effect that is introduced to emulate the reflection and interference of sound inside the cabinet. These are only a few of the possible amplitude envelopes; and when coupled with other filtering effects, the emulation of mechanically-orbited speakers is very realistic. Further, effects can be introduced and controlled to produce sounds not possible with mechanically-orbited speakers.

The physical configuration of sound transducers is key to producing the orbiting speaker sound, but the electronics provide an increased level of control and variation desired for a flexible sound reproduction system. Though the effects described here may be implemented in various technologies, the DSP is powerful and cost effective. This exemplary embodiment will be described in terms of a DSP with embedded software that implements the components of the signal path.

FIG. 24 shows a simplified DSP signal flow diagram 2400. These features may be implemented as software so they may vary, take a different order or have many other features added without changing the present invention. The main instrument input is provided at the connector 2401. A compressor/limiter function 2402 serves the purpose of limiting volume peaks from overdriving the DSP. This effect may be adjusted to compress the dynamic range of the input signal to allow it to sound louder or leave the dynamic range uncompressed until the music peaks would clip in the DSP and only apply enough compression to avoid clipping.

The signal is then split into frequency bands by the highpass 2403, bandpass 2404 and lowpass 2405 filters. The signal from the highpass 2403 filter feeds the tweeters, the bandpass 2404 feeds the mid-range transducers and the lowpass filter 2405 is routed to a line-level output to be connected to the subwoofer. The signal from the PA or alternate instrument input 2406 routed through a similar set of signal function blocks though the parameters, such as distortion models and crossover frequencies may be different from the instrument input 2401 channel.

In this embodiment, the signal from the instrument input is shown as being routed through the amplitude envelope processing 2410, 2411, 2412, 2413, though the PA channel 2406 may optionally be routed through the envelope processing shown or through a separate set of envelope processors.

Envelope processor 2410 imposes an amplitude envelop on the tweeter signal path for the front face. In this example, the amplitude is at maximum at the start of the cycle as the virtual orbiting transducer is facing front. The signal is also at maximum at the start of the cycle for amplitude processor 2411 that is modulating the front face mid-range signal. Envelope processor 2412 and 2413 are modulating the tweeter and mid-range signals for the left face. In this case, we see the tweeter channel becoming maximum in the second quarter of the orbit as the virtual orbiting tweeter moves to the left. On the other hand, the mid-range becomes maximum in the fourth quarter of the orbit as the transducer moves to the right and has to complete three quarters of an orbit to be facing to the left.

The signals output from the envelope processors are then fed to signal mixers and then on to the appropriate amplifiers and sound transducers as shown in FIGS. 12 through 18. The signal output from the envelope processor 2410 is connected to the mixer 2420 associated with the front tweeter and, optionally, through a switch to the mixer for the mid-range. This switch is closed for the low-cost configuration shown in FIG. 14 when used without the tweeter upgrade shown in FIG. 15. When the upgrade is added, the switch is opened to separate the tweeter and mid-range signals. The signal from the lowpass filter is routed directly to the subwoofer signal mixer 2430 and then on to the subwoofer amplifier and transducer. Optionally, a ninth envelope processor may be added to the subwoofer path. The subwoofer envelope may be synchronous with the mid-range or entirely different to emulate a third orbiting sound transducer with its own set of speed and effect depth parameters.

The DSP signal flow diagram 2500 of FIG. 25 shares many of the basic features of FIG. 24 that will not be repeated here. There are some additional features that will be covered here.

The pre-gain adjust 2511, vacuum tube emulator 2512 and post-gain adjust 2513 optionally introduce amplifier distortion emulation to the signal input at 2510. This amplifier emulation takes the form of second-harmonic rich distortion to emulate overdriving the class A preamplifier stage, and third-harmonic rich distortion plus soft compression to emulate the power amplifier stage overdrive. The speaker cabinet emulation may also be introduced at this stage by adding frequency shaping and cabinet induced resonances.

Continuing with the instrument input 2510 signal, it is split into highpass 2515 for the tweeters, mid-range 2516 for the mid-range transducers and lowpass 2517 for the subwoofer. There may be a reverberation emulation block 2530 for each signal path. By splitting the reverberation emulation across the faces of the speaker, a spatial aspect of the reverberation effect is introduced that is lacking the typical front-facing stereo sound system. The signals for the left, right and rear channels have different delays and arrive at the listener from different directions due to room reflections. This better emulates the effect of a larger room. Also, the tweeter and mid-range signal paths are treated differently to add frequency dependent aspects to the effect.

The amplitude envelope processors 2535 operate on each path as described in FIG. 24. Not shown are the optional envelope processors on the PA input 2520, 2525 signal paths. The instrument amplitude envelope processor outputs are routed to the mixer blocks 2540 where the PA signals are combined to drive the appropriate amplifiers and transducers for each face.

Starting at the PA inputs, one for the left 2520 and one for the right 2525 stereo pair, there is a compressor/limiter function 2521 and crossover filters 2522, 2523 and 2524 as described previously. The crossover frequencies for the PA channel may be different from the instrument channel. In particular, the crossover frequencies for the instrument signal path are selected to provide a narrow sound radiation pattern as described in the support for FIGS. 4 and 5. The PA signal paths may have higher crossover frequencies to avoid the narrow radiation patterns of the mid-range and tweeter and achieve a smoother overlap between the faces of the speaker system.

The lowpass 2524 signals from both the left and right PA channels are routed to the subwoofer mixer 2545, because the lowest frequencies have no apparent directional characteristics. The highpass 2522 and mid-range 2523 signals from both the left and right PA channels are routed separately to the mixers 2540. These channels would have further signal processing blocks (not shown) for amplifier and speaker cabinet effects, reverberation and amplitude envelope.

Before the PA channels are mixed, there may be individual gain adjustments to place the stereo image properly by routing the signals to the appropriate face or faces of the speaker system. In a simple example, the left PA tweeter channel from the highpass filter 2522 would be routed with full gain at gain adjustment 2541 to the left tweeter output mixer; and the right channel highpass signal would be routed with full gain through gain adjustment 2543 to the right tweeter output mixer. The left channel mid-range signal from the crossover filter 2523 would be routed with full gain at the gain adjustment 2542, and the right channel signal routed with full gain at gain adjustment 2544 to the right mid-range output mixer. In this simple example, all other gain adjustments would be set to the lowest setting to block the signals. For situations where a broader coverage was desired, the signals at lower gain may be routed to the front and rear faces. This is especially useful in cases where the audience surrounds the player.

Many rotary speaker simulators add harmonic distortion to simulate overdriving the vacuum tube amplifier used in the classic rotating speaker models. This distortion is caused by large peaks in the lower frequency range; and because the distortion is in the vacuum tube amplifier, the harmonics generated by the distortion are lowpass filtered by the amplifier output transformer. This distortion is emulated in the DSP or other electronic circuits of the present invention.

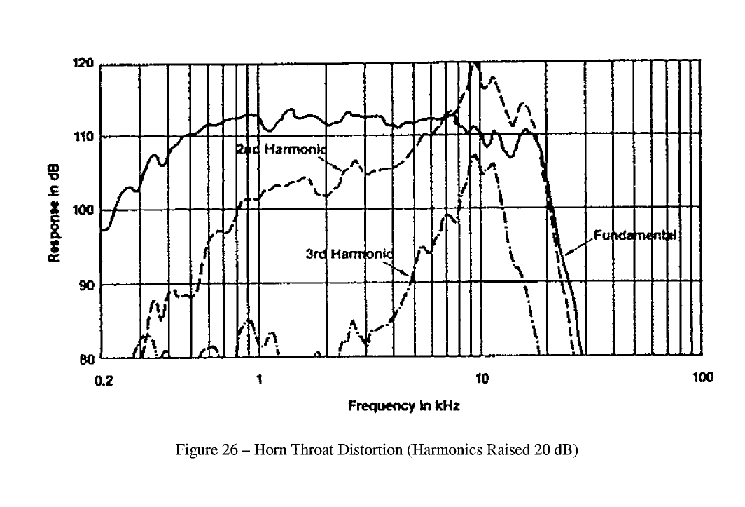

A second type of distortion is a part of the characteristic sound of these classic speakers and that is horn throat-distortion caused by the nonlinearity of the air in the throat of the horn under high compression of volume peaks. Horns with long narrow throats, such as those used in the classic orbiting speakers, are especially subject to throat distortion. This type of distortion rises with frequency, as shown in FIG. 26, and gives the classic speakers a special biting sound on musical peaks.

Horn throat-distortion is emulated in the DSP and is particularly valuable for the simple models operated without the horn upgrade. In the DSP, a separate signal path (not shown) is used where the signal is filtered with a 3 dB per octave rise with frequency, peaking at 8 KHz. This signal is modified to produce 2^{nd} harmonic with 3^{rd} harmonic 10 dB lower.

The resulting distortion signal is summed with the primary signal through a variable gain. This variable gain may be player selectable or adjustable to produce the desired amount of horn throat-distortion effect.

The horn throat-distortion effect may be automatically disabled when a horn upgrade unit is associated with the master unit. The user may have the option to override the automatically disabled horn throat-distortion effect when the horn upgrade unit is associated to add the simulated effect with that of the real horns.

One attraction of mechanical-orbiting or rotating speakers is that with the cabinet back or top removed, the listeners can view the spinning horn and drum and associate the change in speed with the changes in sound. Especially for keyboard players where the action of playing is often hidden by the instrument, some physical evidence of live performance is welcome. Therefore, an optional feature is a string or series of lights in the plane of the virtual orbiting transducer. The lights would light in a pattern that indicates the motion of the virtual orbiting transducer under control of the DSP. The string of lights may be duplicated for each set of orbiting transducers and in synchronism with the associated virtual transducer.

As can be seen from the long list of features the electronically-orbited speaker system produces, the sound of classic orbiting speakers while achieving many advantages, such as ease of transport, upgradability, higher sound level output and operation with two or more sound systems with independent characteristics.

Those of skill would appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components, blocks, modules, circuits, and steps above have been described generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the exemplary embodiments disclosed herein may be embodied directly in hardware, in a software module executed by a processor, or in a combination of the two. A software module may reside in Random Access Memory (RAM), flash memory, Read Only Memory (ROM), Electrically Programmable ROM (EEPROM), Electrically Erasable Programmable ROM (EEPROM), registers, hard disk, a removable disk, a CD, DVD, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in an electronically orbited speaker. In the alternative, the processor and the storage medium may reside as discrete components in an electronically-orbited speaker.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer By way of example, and not limitation, such computer-readable media can comprise RAM, ROM, EEPROM, Flash, CD, DVD or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the sprit or scope of the invention. Thus, the present invention is not intended to be limited to the exemplary embodiments shown herein but is to be accorded the widest scope consistent with the principles and novel features disclosed herein.

What I claim is:

1. An apparatus for sound amplification and modification, comprising:
a plurality of sound transducers configured to direct sound in different directions; and
a plurality of amplifiers operably coupled with the sound transducers; and
an electronic signal processor operably coupled to the amplifiers; and
the signal processor configured to receive a sound signal, divide the signal into a plurality of signals, modulate each divided signal with a separate amplitude envelope and couple each modulated signal to one or more of the amplifiers; and
the signal processor is further configured to modulate the divided signals in a manner that causes the sound source to orbit.

2. The apparatus of claim 1, wherein the orbiting of the sound source imposes amplitude and frequency modulation on the sound.

3. The apparatus of claim 1, wherein at least one of the amplifiers is operably coupled to a plurality of sound transducers arranged to direct the sound output in a single direction; and
the dimension of transducer separation is selected to enhance the effect of orbiting of the sound.

4. The apparatus of claim 3, wherein each of the sound transducers are configured to drive a separate front loaded horn; and
each of the horns is configured to place the apparent sound source of the individual transducer close to the edge of the enclosure.

5. The apparatus of claim 1, wherein at least a portion of the apparatus is configured to mount on a pole or a speaker stand, or to rest or mount on top of another portion of the apparatus.

6. The apparatus of claim 1, wherein the signal processor is further configured to use different amplitude envelopes.

7. The apparatus of claim 1, wherein the signal processor is further configured to delay a portion of each divided signal separately to introduce a spatial reverberation effect.

8. The apparatus of claim 1, wherein the signal processor is further configured to receive a second sound signal, different from the first sound signal; and
divide the second signal into a plurality of signals; and
optionally modulate each divided signal; and
optionally delay a portion of each divided signal; and
couple each divided signal to one or more of the amplifiers.

9. The apparatus of claim 1, wherein the signal processor is further configured to divide the sound signal into frequency bands associated with separate sound transducers; and
the transducers have sound reproduction characteristics appropriate for the band of operation.

10. The apparatus of claim 1, wherein the apparatus is further configured to have player control over at least one of the parameters of speed of orbiting, direction of orbiting, acceleration between speeds and deceleration between speeds.

11. The apparatus of claim 1, wherein the apparatus is further configured to modulate the divided signals in a manner that causes there to be a plurality of orbiting sound sources.

12. The apparatus of claim 1, wherein the apparatus is further configured to impose the effect of horn-throat distortion on at least one signal.

13. The apparatus of claim 1, wherein the apparatus is further configured to interface audio and control signals compatible with classical tonewheel organs, or in an analog or digital format, or a combination thereof.

14. The apparatus of claim 1, wherein the signal processor is further configured to control a series or a plurality of series of lights in a manner that suggests the orbiting of the sound source or sources.

15. A method for sound amplification and modification, comprising:
receiving a sound signal by a signal processor, dividing the signal into a plurality of signals, modulating each divided signal with a separate amplitude envelope and coupling each modulated signal to one or more amplifier; and
amplifying the signals by a plurality of amplifiers; and
directing sound in different directions by a plurality of sound transducers; and
modulating the divided signals by the signal processor in a manner that causes the sound source to orbit.

16. A computer program product, comprising:
a computer-readable medium comprising:
code for controlling receiving a sound signal by a signal processor, dividing the signal into a plurality of signals, modulating each divided signal with a separate amplitude envelope and coupling each modulated signal to one or more amplifier; and
code for controlling amplifying the signals by a plurality of amplifiers; and
code for controlling directing sound in different directions by a plurality of sound transducers; and
code for modulating the divided signals in a manner that causes the sound source to orbit.
